(19) United States
(12) Patent Application Publication
(10) Pub. No.: US 2012/0189765 A1
(43) Pub. Date: Jul. 26, 2012

(54) PAINT CURING MEASUREMENT SYSTEM AND METHOD

(75) Inventors: CHI-CHIH WANG, Tu-Cheng (TW); RUI-JUN WANG, Shenzhen City (CN); ZHI-LONG LI, Shenzhen City (CN); YAO-FENG LI, Shenzhen City (CN)

(73) Assignees: HON HAI PRECISION INDUSTRY CO., LTD., Tu-Cheng (TW); GDS SOFTWARE (SHENZHEN) CO.,LTD, ShenZhen City (CN)

(21) Appl. No.: 13/217,256

(22) Filed: Aug. 25, 2011

(30) Foreign Application Priority Data
Jan. 26, 2011 (CN) 201110024939.8

(51) Int. Cl. C23C 16/52; B05C 11/00

(52) U.S. Cl. 427/8; 118/697

(57) ABSTRACT

In a paint curing measurement system and method, the number of products input to an paint curing production line, the frequency of spraying primer on the surfaces of the products, the frequency of drying the primer on the surfaces of the products, a frequency of spraying topcoat on the surfaces of the products, and a yield of the products are calculated. Accordingly, production performance of the paint curing production line is determined. The production performance is output to an output device.

### BACKGROUND

1. Technical Field

Embodiments of the present disclosure relate to measurement systems and methods, and particularly to a paint curing measurement system and method.

2. Description of Related Art

Painting process for a product is very important. Paint can make the product more sleek and good-looking. In order to take actions to improve the painting process, production performance of a paint curing production line is required to be measured.

### BRIEF DESCRIPTION OF THE DRAWINGS

FIG. 1 is a block diagram of one embodiment of an application environment of a paint curing measurement system.

FIG. 2 is a detailed block diagram of one embodiment of a paint curing production line in FIG. 1.

FIG. 3 is a block diagram of one embodiment of a measurement unit in FIG. 1.

FIG. 4 is a flowchart of one embodiment of a paint curing measurement method.

### DETAILED DESCRIPTION

The disclosure is illustrated by way of examples and not by way of limitation in the figures of the accompanying drawings in which like references indicate similar elements. It should be noted that references to “an” or “one” embodiment in this disclosure are not necessarily to the same embodiment, and such references mean at least one.

In general, the word “module”, as used herein, refers to logic embodied in hardware or firmware, or to a collection of software instructions, written in a programming language, such as, Java, C, or assembly. One or more software instructions in the modules may be embedded in firmware, such as in an EPROM. The modules described herein may be implemented as either software and/or hardware modules and may be stored in any type of non-transitory computer-readable medium or other storage device. Some non-limiting examples of non-transitory computer-readable media include CDs, DVDs, BLU-RAY, flash memory, and hard disk drives.

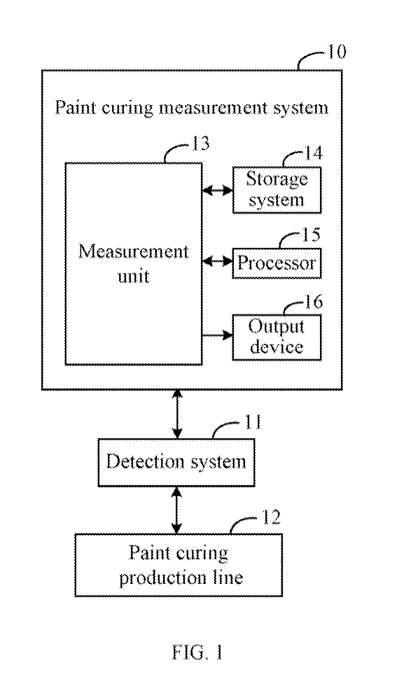

FIG. 1 is a block diagram of one embodiment of an application environment of a paint curing measurement system 10. In the embodiment, the paint curing measurement system 10 may be electronically connected to a detection system 11 that obtains detection data of an paint curing production line 12. The paint curing measurement system 10 determines production performance of the paint curing production line 12 according to the detection data. The detection system 11 may obtain the detection data (e.g., the number of the products). In one embodiment, the detection system 11 includes one or more sensors (e.g., infrared sensors or microwave sensors). The one or more sensors may be positioned in the paint curing production line 12 and is used to obtain the diction data. The paint curing measurement system 10 may be a data processing device or a computerized device such as a personal computer, an application server, or a workstation, for example. In one embodiment, the product may be, but is not limited to, a component of a mobile phone (e.g., a back cover).

In one embodiment, the paint curing measurement system 10 includes a measurement unit 13, a storage system 14, a processor 15, and an output device 16. One or more computerized codes of the measurement unit 13 may be stored in the storage system 14 and executed by the processor 15. The storage system 14 may include a flash memory, a hard disk drive, and a cache. The output device 16 may be a display screen or a printer, which outputs measurement results of the paint curing production line 12 to users.

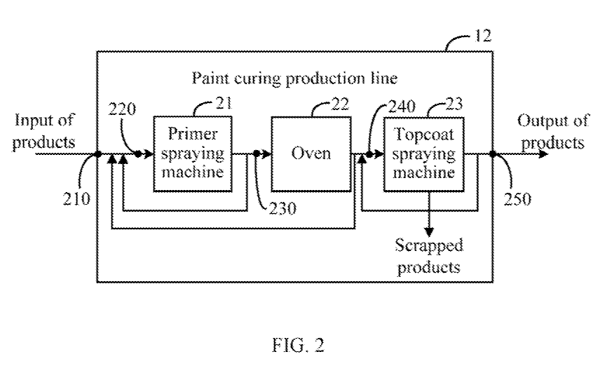

FIG. 2 is a detailed block diagram of one embodiment of the paint curing production line 12 in FIG. 1. In the embodiment, the paint curing production line 12 may include a primer spraying machine 21, an oven 22, and a topcoat spraying machine 23. The primer spraying machine 21 may spray a primer on the surface of the products. It is understood that the primer is defined as an base paint that is designed to adhere to the surface of the products to form a binding layer on the surface of the products. The primer ensures better adhesion of paint to the surface of the products, increases paint durability, and provides additional protection for the product being painted. The oven 22 dries the primer on the surface of the products using high temperatures (e.g., 200 degrees Celsius). The topcoat spraying machine 23 sprays the topcoat on the surface of the products. It is understood that the topcoat is defined as a finishing paint that is designed to adhere to the primer to form a smooth layer on the surface of the products. A user can use the topcoat to create a predetermined figure (e.g., a rabbit figure) or a word (e.g., a name of a brand) on the surface of the product.

In painting, if the primer spraying machine 21 fails to uniformly spray the primer on the surface of products, the products need to be reflowed to the primer spraying machine 20. For example, if the primer is not sprayed on an area of a surface of the a product, the product needs to be sprayed with the primer again by reflowing the product to the primer spraying machine 21. If the oven 22 fails to dry the primer to adhere to the surfaces of the products, the products need to be sprayed primer again and reflowed to the oven 22. For example, if the surface of a product has foam, or the primer drops from the surface of the product, the product needs to be reflowed to the primer spraying machine 21 and the oven 22. If the topcoat spraying machine 23 fails to uniformly spray the topcoat on the surfaces of the products, the products need to be reflowed to the topcoat spraying machine 23. For example, if the topcoat is not sprayed on an area of the surface of a product, the product needs to be sprayed with the topcoat again by reflowing the product to the topcoat spraying machine 23. A product may become defective and un-repairable if the product fails to reflow the topcoat spraying machine 23. In this case, the product is scrapped. In one embodiment, the detection system 11 arranges sensors 210-250 positioned in the paint curing production line 12 as shown in FIG. 2, to obtain the detection data of the paint curing production line 12. Further details will be described below.

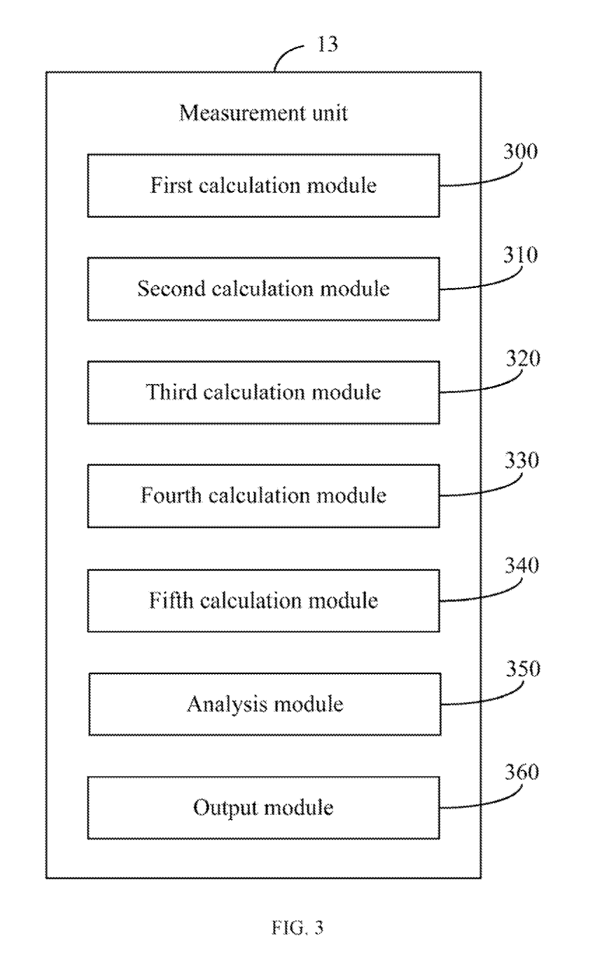

FIG. 3 is a block diagram of one embodiment of the measurement unit 13 in FIG. 1. In one embodiment, the measurement unit 13 may include a first calculation module 300, a second calculation module 310, a third calculation module 320, a fourth calculation module 330, a fifth calculation module 340, an analysis module 350, a detection module 360, and an output module 370.

The first calculation module 300 calculates the number of products input to the paint curing production line 12. In one embodiment with respect to FIG. 2, the first calculation module 300 uses the sensor 210 positioned at an entrance of the paint curing production line 12 to detect products entering the paint curing production line 12. Accordingly, the first calculation module 300 calculates the number of the products. In one example, the number of the products is ten.

The second calculation module 310 calculates the frequency of the primer spraying machine 21 spraying primer on the surfaces of the products. In one embodiment with respect to FIG. 2, the second calculation module 310 may use the sensor 220 positioned at an entrance of the primer spraying machine 21 to detect products going into the primer spraying machine 21. Accordingly, the second calculation module 310 calculates the frequency of spraying the primer on the surfaces of the products. In one example, the frequency of spraying the primer on the surfaces of the products is fifteen.

The third calculation module 320 calculates the frequency of the oven 22 drying the primer on the surfaces of the products. In one embodiment with respect to FIG. 2, the third calculation module 320 may use the sensor 230 positioned at the entrance of the oven 22 to detect the products going into the oven 22. Accordingly, the third calculation module 320 calculates the frequency of drying the primer on the surfaces of the products. In one example, the frequency of drying the primer on the surfaces of the products is twelve.

The fourth calculation module 320 calculates the frequency of the topcoat spraying machine 23 spraying topcoat of the surfaces of the products. In one embodiment with respect to FIG. 2, the fourth calculation module 330 may use the sensor 240 positioned at an entrance of the topcoat spraying machine 23 to detect the products going into the topcoat spraying machine 23. Accordingly, the fourth calculation module 330 calculates the frequency of spraying topcoat on the surfaces of the products. In one example, the frequency of spraying topcoat on the surfaces of the products is thirteen.

The fifth calculation module 340 calculates a yield of the products in the paint curing production line 12. In one embodiment with respect to FIG. 2, the fifth calculation module 340 uses the sensor 250 positioned at an exit of the paint curing production line 12 to detect products output from the paint curing production line 12. Accordingly, the fifth calculation module 340 calculates the yield of the products. It may be understood that products output from the paint curing production line 12 are quality products. In one example, the yield of the products is nine.

The analysis module 340 analyzes production performance of the paint curing production line 12 according to the number of the products, the frequency of spraying the primer on the surfaces of the products, the frequency of drying the primer on the surfaces of the products, the frequency of spraying the topcoat on the surfaces of the products, and the yield of the products. In one embodiment, the analysis module 340 may calculate a first time yield rate of spraying the primer on the surfaces of the products, a first time yield rate of drying the primer on the surfaces of the products, a first time yield rate of spraying the topcoat on the surfaces of the products, and a total yield rate of paint curing production line 12 to determine the production performance of the paint curing production line 12. Further details will be described below.

The output module 360 outputs the production performance of the paint curing production line 12 to the output device 16. In one embodiment, the output module 360 outputs the first time yield rate of spraying the primer on the surfaces of the products, the first time yield rate of drying the primer on the surfaces of the products, the first time yield rate of spraying the topcoat on the surfaces of the products, and the total yield rate of paint curing production line 12 to the output device 16.

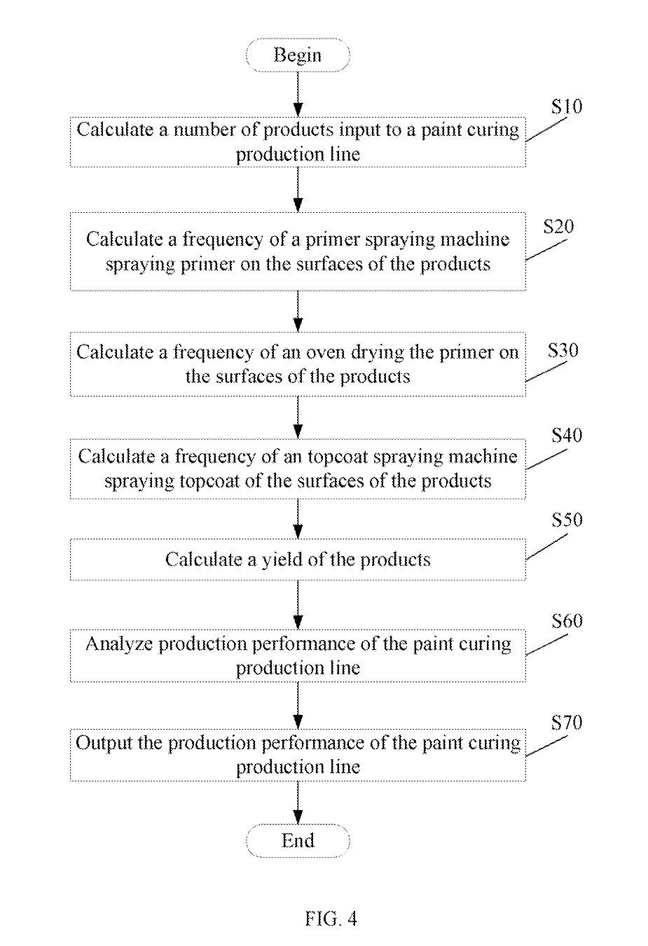

FIG. 4 is a flowchart of one embodiment of a paint curing measurement method implementing a paint curing measurement system, such as that in FIG. 1. The method may be used to analyze production performance of the paint curing production line 12. Depending on the embodiments, additional blocks may be added, others removed, and the ordering of the blocks may be changed.

In block S10, the first calculation module 300 calculates a number of products input to the paint curing production line 12. In one embodiment with respect to FIG. 2, the sensor 210 may be positioned at the entrance of the paint curing production line 12. The sensor 210 may signal the first calculation module 300 when detecting a product entering the paint curing production line 12. The first calculation module 300 may increase the number of products by one when signaled by the sensor 210. In one example, the number of the products is ten.

In block S20, the second calculation module 310 calculates the frequency of the primer spraying machine 21 spraying primer on the surfaces of the products. As mentioned above, a product may be reflowed to the primer spraying machine 21 if the primer spraying machine 21 fails to uniformly spray primer on the surface of the product, or if oven 22 fails to dry the primer on the surface of the product. Therefore, the frequency of spraying the primer on the surface of the products may be larger than the number of the products due to the rework. In one example, the number of products is ten, and the frequency of spraying the primer on the surfaces of the products is fifteen. In one embodiment with respect to FIG. 2, the detection system 11 may position the sensor 220 before the primer spraying machine 21. The sensor 220 may signal the second calculation module 310 when detecting a product going into the primer spraying machine 21. The second calculation module 310 may increase the frequency of spraying the primer on the surface of products by one when signaled by the sensor 220.

In block S30, the third calculation module 320 calculates the frequency of the oven 22 drying the primer on the surfaces of the products. As mentioned above, the surface of the products may have foams or the primer drops from the surface of the products. Therefore, the frequency of drying primer on the surfaces of the products may be larger than the number of the products due to rework. In one example, the number of products is ten, and the frequency of drying the primer on the surfaces of the products is fifteen. In one embodiment with respect to FIG. 2, the detection system 11 may position the sensor 230 before the oven 22. The sensor 230 may signal the third calculation module 320 when detecting a product entering into the oven 22. The third calculation module 320 may increase the frequency of drying the primer on the surfaces of the products by one when signaled by the sensor 230.

In block S40, the forth calculation module 320 calculates the frequency of the topcoat spraying machine 23 spraying topcoat of the surfaces of the products. As mentioned above, a product may be reflowed to the topcoat spraying machine 23 if the topcoat spraying machine 21 fails to uniformly spray topcoat on the surface of the product. Therefore, the frequency of spraying the topcoat on the surfaces of the products may be larger than the number of the products due to the rework. In one example, the number of products is ten, and the frequency of spraying topcoat on the surfaces of the products is fifteen. In one embodiment with respect to FIG. 2, the detection system 11 may position the sensor 240 before the topcoat spraying machine 23. The sensor 240 may signal the fourth calculation module 310 when detecting a product going into the topcoat spraying machine 23. The forth calculation module 330 may increase the frequency of spraying topcoat on the surfaces of products by one when signaled by the sensor 240.

In block S50, the fifth calculation module 340 calculates a yield of the products in the paint curing production line 12. As mentioned above, a product may be scrapped if the product becomes defective and un-repairable. Therefore, the yield of the products may be less than the number of the products due to scrap. In one example, the number of the products is ten, and the yield of the products is nine. In one embodiment, the detection system may position the sensor 250 after the topcoat spraying machine 23. The sensor 250 may signal the fifth calculation module 340 if detecting a product output from the paint curing production line twelve. The fifth calculation module 340 may increase the yield of the products by one when signaled by the sensor 250.

In block S60, the analysis module 350 analyzes production performance of the paint curing production line 12 according to the number of the products, the frequency of spraying the primer on the surfaces of the products, the frequency of drying the primer on the surfaces of the products, the frequency of spraying the topcoat on the surfaces of the products, and the yield of the products. In one embodiment, the analysis module 340 may calculate a first time yield rate of spraying the primer on the surfaces of the products, a first time yield rate of drying the primer on the surfaces of the products, a first time yield rate of spraying the topcoat on the surfaces of the products, and a total yield rate of paint curing production line 12 to determine the production performance of the paint curing production line 12.

In one example, the number of the products is denoted as N1, the frequency of spraying the primer on the surface of the products is denoted as N2, the frequency of drying the primer on the surface of the products is denoted as N3, the frequency of spraying the topcoat on the surface of the products is denoted as N4, and the total yield of the paint curing production line 12 is denoted as N5. The first time yield rate of spraying the primer on the surface of the products may be calculated as [N1−(N2−N3)]/N1. The first time yield rate of drying the primer on the surface of the products may be calculated as [N1−(N3−N1)]/N1. The first time yield rate of spraying the topcoat on the surface of the products may be calculated as [N1−(N4−N1)]/N1. The total yield rate of the paint curing production line 12 may be calculated as N5/N1. In one example, the number of the products is ten, the frequency of spraying the primer on the surface of the products is fifteen, the frequency of drying the primer on the surface of the products is twelve, the frequency of spraying the topcoat on the surface of the products is thirteen, and the yield of the PCBs is nine. Therefore, the first time yield rate of spraying the primer on the surface of the products is 70%. The first time yield rate of drying the primer on the surface of the products is 80%. The first time yield rate of spraying the topcoat on the surface of the products is 70%. The total yield rate of the paint curing production line 12 is 90%.

In block S60, the output module 360 outputs the production performance of the paint curing production line 12 to the output device 16. In one embodiment, the output module 360 outputs the first time yield rate of spraying the primer on the surfaces of the products, the first time yield rate of drying the primer on the surfaces of the products, the first time yield rate of spraying the topcoat on the surfaces of the products, and the total yield rate of paint curing production line 12 to the output device 16. The output module 360 may further signal an alarm message to the output device. For example, if the first time yield rate of spraying the primer on the surface of the products is below 70%, the first time yield rate of drying the primer on the surface of the products is below 80%, the first time yield rate of spraying the topcoat on the surface of the products is below 70%, or the total yield rate of paint curing production line 12 is below 85%, the output module 360 may signal an alarm message to the output device so that the user can be aware of the problem easily and quickly.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A paint curing measurement system, the measurement system in electronic communication with a paint curing production line comprising a primer spraying machine, an oven and a topcoat spraying machine, the measurement system comprising:
a storage system;
at least one processor;
one or more programs stored in the storage system and being executable by the at least one processor, the one or more programs comprising:
a first calculation module operable to calculate a number of products input to the paint curing production line;
a second calculation module operable to calculate a frequency of the primer spraying machine spraying primer on the surfaces of the products;
a third calculation module to operable to calculate a frequency of the oven drying the primer on the surfaces of the products;
a fourth calculation module operable to calculate a frequency of the topcoat spraying machine spraying topcoat of the surfaces of the products;
a fifth calculation module operable to calculate a yield of the products in the paint curing production line; and
an analysis module operable to analyze production performance of the paint curing production line according to the number of the products, the frequency of spraying the primer on the surfaces of the products, the frequency of drying the primer on the surfaces of the products, the frequency of spraying the topcoat on the surfaces of the products, and the yield of the products.

2. The measurement system of claim 1, wherein the analysis module calculates a first time yield rate of spraying the primer on the surfaces of the products, a first time yield rate of drying the primer on the surfaces of the products, a first time yield rate of spraying the topcoat on the surfaces of the products, and a total yield rate of paint curing production line.

3. The measurement system of claim 2, wherein the performance of the paint curing production line is determined by the first time yield rate of spraying the primer on the surfaces of the products, the first time yield rate of drying the primer on the surfaces of the products, the first time yield rate of spraying the topcoat on the surfaces of the products, and the total yield rate of paint curing production line.

4. The measurement system of claim 1, wherein system further comprises a output module operable to output the production performance of the paint curing production line to an output device.

5. The measurement system of claim 4, wherein the output module further outputs an alarm message to the output device.

6. The measurement system of claim 4, wherein the output device is a display screen or a printer.

7. A paint curing measurement method, comprising:
calculating a number of products input to a paint curing production line, wherein the paint curing production line comprises a primer spraying machine, an oven and a topcoat spraying machine;
calculating a frequency of the primer spraying machine spraying primer on the surfaces of the products;
calculating a frequency of the oven drying the primer on the surfaces of the products;
calculating a frequency of the topcoat spraying machine spraying topcoat of the surfaces of the products;
calculating a yield of the products in the paint curing production line; and
analyzing production performance of the paint curing production line according to the number of the products, the frequency of spraying the primer on the surfaces of the products, the frequency of drying the primer on the surfaces of the products, the frequency of spraying the topcoat on the surfaces of the products, and the yield of the products.

8. The method of claim 7, wherein the analysis module calculates a first time yield rate of spraying the primer on the surfaces of the products, a first time yield rate of drying the primer on the surfaces of the products, a first time yield rate of spraying the topcoat on the surfaces of the products, and a total yield rate of paint curing production line.

9. The method of claim 8, wherein the performance of the paint curing production line is determined by the first time yield rate of spraying the primer on the surfaces of the products, the first time yield rate of drying the primer on the surfaces of the products, the first time yield rate of spraying the topcoat on the surfaces of the products, and the total yield rate of paint curing production line.

10. The method of claim 7, further comprising:
outputting the production performance of the paint curing production line to an output device.

11. The method of claim 10, wherein the output module further outputs an alarm message to the output device.

12. The method of claim 10, wherein the output device is a display screen or a printer.

13. A non-transitory computer-readable medium having stored thereon instructions that, when executed by at least one processor of a computerized device, causes the computerized device to execute a paint curing measurement method, the method comprising:
calculating a number of products input to a paint curing production line, wherein the paint curing production line comprises a primer spraying machine, an oven and a topcoat spraying machine;
calculating a frequency of the primer spraying machine spraying primer on the surfaces of the products;
calculating a frequency of the oven drying the primer on the surfaces of the products;
calculating a frequency of the topcoat spraying machine spraying topcoat of the surfaces of the products;
calculating a yield of the products in the paint curing production line; and
analyzing production performance of the paint curing production line according to the number of the products, the frequency of spraying the primer on the surfaces of the products, the frequency of drying the primer on the surfaces of the products, the frequency of spraying the topcoat on the surfaces of the products, and the yield of the products.

14. The computer-readable medium of claim 11, wherein the method further comprises:
calculating a first time yield rate of spraying the primer on the surfaces of the products, a first time yield rate of drying the primer on the surfaces of the products, a first time yield rate of spraying the topcoat on the surfaces of the products, and a total yield rate of paint curing production line.

15. The computer-readable medium of claim 14, wherein the performance of the paint curing production line is determined by the first time yield rate of spraying the primer on the surfaces of the products, the first time yield rate of drying the primer on the surfaces of the products, the first time yield rate of spraying the topcoat on the surfaces of the products, and the total yield rate of paint curing production line.

16. The computer-readable medium of claim 11, wherein the method further comprises:
outputting the production performance of the paint curing production line to an output device wherein the output device is a display screen or a printer.

17. The computer-readable medium of claim 16, wherein the output module further outputs an alarm message to the output device.

18. The computer-readable medium of claim 16, wherein the output device is a display screen or a printer.
